(19) United States
(12) Patent Application Publication
(10) Pub. No.: US 2007/0169695 A1
(43) Pub. Date: Jul. 26, 2007

(54) Process and device for coating strips

(76) Inventors: Holger Schneiders, Alsdorf (DE); Rudolf Thyen, Hamburg (DE); Juan Rechid, Hamburg (DE)

Correspondence Address: Friedrich Kueffner, Suite 910, 317 Madison Avenue, New York, NY, 10017, US

(21) Appl. No.: 11/636,363

(22) Filed: Dec. 8, 2006

(30) Foreign Application Priority Data
Dec. 9, 2005 (DE) 10 2005 058 869.7

(51) Int. Cl. C23C 16/00; C23C 14/00

(52) U.S. Cl. 118/718; 118/50

(57) ABSTRACT

A process and a device for coating a strip in which the strip is transported along a strip guide inside a coating chamber. At least two guide elements of the strip guide are positioned a certain distance apart, their longitudinal axes being arranged at a slant to each other in such a way that the distance between the guide elements varies along the longitudinal axes. The strip is conducted along the guide elements inside the coating chamber in such a way that at least two sections of the strip are traveling essentially adjacent to each other as they are being coated.

### BACKGROUND OF THE INVENTION

1. Field of the Invention

The present invention relates to a strip-coating process in which the strip is transported inside a coating chamber along a strip guide.

The invention also relates to a device for coating a strip, wherein the device is equipped with a strip guide in a coating chamber.

2. Description of the Related Art

Narrow metal strips with widths in the range of 1-10 cm are coated at low cost by electroplating. For example, solderable substrates can be produced by plating narrow strips of copper with tin. Many materials, however, cannot be electroplated at all or can be electroplated only with great difficulty. Such materials include Ti, V, Mn, Zr, Nb, Mo, Ta, and W. This is described, for example, on page 22 of Tabellenbuch der Galvanotechnik [Book of Electroplating Tables] by J. N. M. Unruh (ISBN 3-87480-165-9, Eugen G. Leutze Verlag, 7th edition, 2001). Similar problems exist with ceramic materials (oxides, nitrides) such as SiOₓ, TiOₓ, Znₓ, AlN, and SiN. In addition, strips which do not conduct electricity cannot be coated by the electroplating process.

In such cases other processes are used, such as physical vapor deposition (PVD), close space sublimation (CSS), cathodic atomization (sputtering), and chemical vapor deposition (CVD) such as plasma-activated CVD (PACVD) and plasma-enhanced CVD (PECVD). These technologies are described by Rene A. Haefer in Oberflächen- und Dünnschicht-Technologie [Surface and Thin-Layer Technology], Part I, Surface Coatings, page 3 ff., ISBN 3-540-16723-4, Springer-Verlag, Berlin-Heidelberg-N.Y.

The above-heated vacuum coating processes usually apply their coatings over a large surface area. As a result, when a single, narrow, moving strip is being coated, a large amount of coating material is deposited next to the strip and therefore lost. The degree of material utilization is therefore low.

Aside from the cost of labor, the economy of a coating process is determined essentially by the degree of material utilization (operating costs) and by the production equipment required (investments). The wider the area to be coated, the better the material utilization rate. If, for other reasons, however, the strip to be coated must be narrow (e.g., <10 cm), the material utilization rate can be improved by conducting several strips in parallel and then even more by minimizing the distance between the strips. The complexity of the equipment required for the automatic control of strip guidance, however, increases rapidly with the number of parallel strips to be guided.

In the case of vacuum or negative-pressure applications, the following processes, for example, can be conducted:
sputtering,
vapor deposition,
thermal CVD,
plasma-activated CVD (PACVD, PECVD),
gas-phase reactions (e.g., atomic layer epitaxy (ALE), molecular beam epitaxy (MBE)), and
dry etching processes (e.g., reactive ion etching (RIE)).

It is also possible, however, to perform certain applications under standard pressure conditions (atmospheric pressure). In the case of applications under standard pressure or at only slight negative or positive pressures, the following processes can be used:

spraying under inert gas (e.g., ion layer gas reaction (ILGAR),
gas-phase reactions (ILGAR, atmospheric pressure CVD),
chemical bath deposition (CBD),
atmospheric-pressure plasma processes (dielectric barrier discharge, pulsed arc discharge, corona discharge),
wet etching processes, and
thermal processes.

### SUMMARY OF THE INVENTION

For a process of the type indicated above, the invention is based on the object of guiding a single narrow strip in a special strip guide arrangement in such a way that economical coatings can be obtained by the use of standard coating processes. As explained above, this leads to a high material utilization rate at comparatively low investment cost.

This object is met according to the invention in that
the longitudinal axes of at least two guide elements of the strip guide, which are positioned a certain distance apart, are slanted relative to each other in such a way that these longitudinal axes lie on planes which are a certain distance apart and essentially parallel to each other, where the distance between the guide elements varies along the longitudinal axes; and in that
the strip is conducted over the guide elements inside the coating chamber in such a way that at least two sections of strip are essentially adjacent to each other. As a result, two two-dimensional areas are formed, at least one of which can be used for coating.

An additional object of the invention is to design a device of the type indicated above in such a way that high-quality coatings can be produced on strips with high economic efficiency.

This task is accomplished according to the invention in that the strip guide is provided with at least two guide elements arranged a certain distance apart, the longitudinal axes of these guides being slanted relative to each other, where the longitudinal axes lie on planes which are a certain distance apart and essentially parallel to each other, and where the distance between the guide elements changes along the longitudinal axis; and in that the guide elements are arranged in such a way that at least two sections of strip are essentially adjacent to each other.

Because the longitudinal axes of the guide elements are arranged at a slant to each other, the direction of the strip is changed in the area of the guide elements in such a way that the strip can be looped around the guide elements while lying with full two-dimensional contact on them. It is therefore possible to avoid slippage almost completely.

The reliability and protectiveness with which the material is guided can be improved even more by conducting the strip over rotationally symmetric guide elements, preferably roll-like guide elements, especially cylindrical guide elements. In a special form of embodiment, the strip is conducted over conical guide elements.

A typical embodiment consists in that a strip consisting essentially of metal is coated.

It is also possible for a strip consisting essentially of plastic to be coated.

According to another embodiment, a strip consisting essentially of textile material is coated.

With respect to the guidance of the material, it has been found to be especially advantageous for the strip to lie with full two-dimensional contact as it is being conducted over the guide elements.

So that temperature can be allowed to act on the strip, it is proposed that at least one of the guide elements be tempered.

According to a special embodiment, at least one of the guide elements is heated.

It is also possible for at least one of the guide elements to be cooled.

To avoid or to reduce slippage, it is proposed that the strip be put under tension.

According to an advantageous embodiment, a multi-layer coating is produced.

Uniform, relatively thick coatings can be achieved by coating the strip several times with the same material.

A combination of different material properties can be achieved by coating the strip with at least two different materials or material properties.

An especially preferred application is to coat a strip intended to serve as a basis material for solar cells.

As the strip is being deflected in the area of the strip guide, an optimal change of direction is obtained by slanting the longitudinal axes with respect to each other by an angle in the range of 0.1-45°, preferably by an angle in the range of 1-10°.

The construction of large systems can be facilitated by dividing at least one of the guide elements into at least two segments in the direction of the longitudinal axis.

The various features of novelty which characterize the invention are pointed out with particularity in the claims annexed to and forming a part of the disclosure. For a better understanding of the invention, its operating advantages, specific objects attained by its use, reference should be had to the drawing and descriptive matter in which there are illustrated and described preferred embodiments of the invention.

### BRIEF DESCRIPTION OF THE DRAWING

In the drawings:

FIG. 1 is a front view of two roll-like guide elements, mounted a certain distance apart, over which a strip is passing;

FIG. 2 is a side view in direction II of FIG. 1;

FIG. 3 is a top view in direction III of FIG. 1;

FIG. 4 shows a strip guide roll with a surface which is provided with convexities;

FIG. 5 is a front view of two segmented strip guide rolls;

FIG. 6 is a side view in direction VI of FIG. 5;

FIG. 7 is a top view of a strip guide element made up of several slanted strip guide disks 12, which are parallel to each other;

FIG. 8 is a partial cross-sectional and highly schematic front view of a vacuum coating system;

FIG. 9 is a top view in direction XI of FIG. 8; and

FIG. 10 is a partial cross-sectional and highly schematic front view of a normal-pressure coating system.

### DETAILED DESCRIPTION OF THE INVENTION

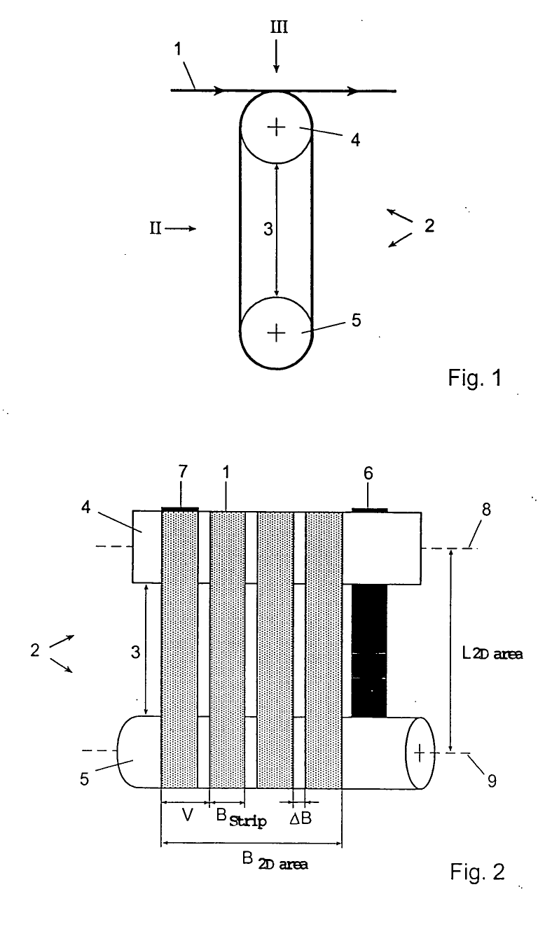

According to the embodiment shown in FIG. 1, a strip 1 to be coated is conducted over a strip guide 3, which is made up of two guide elements 4, 5 arranged a certain distance apart.

FIG. 2 shows a side view, which illustrates that the guide elements 4, 5 are designed as rolls, where the uncoated strip 1 is fed to the strip guide 2 in the area of a strip inlet 6, while the coated strip 1 is taken away in the area of a strip outlet 7. The longitudinal axes 8, 9 of the guide elements 4, 5 are a certain distance (L_{2Darea}) apart. The individual loops of the strip are separated by gaps AB, and the complete set of loops passing around the guide elements 4, 5 extend over an effective width of B_{2Darea}.

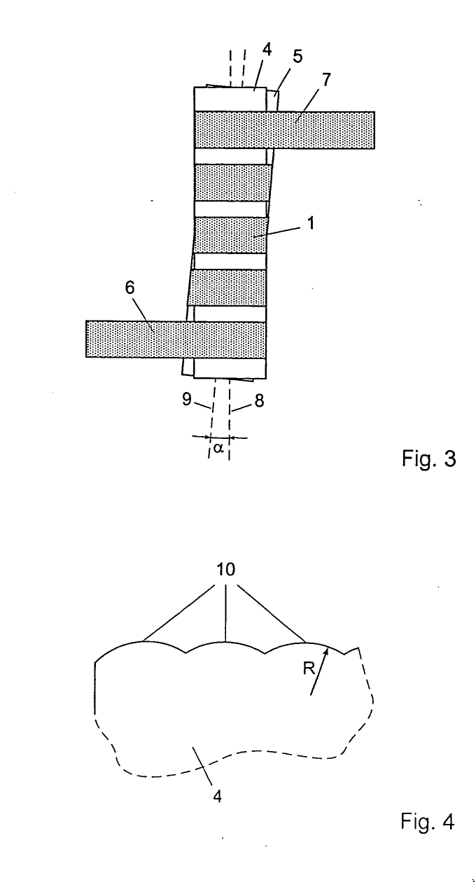

FIG. 3 shows the arrangement according to FIGS. 1 and 2 from above in viewing direction III. It can be seen that the longitudinal axes 8, 9 are arranged at a slant to each other at an angle α.

FIGS. 1-3 show a strip guide arrangement, in which the strip 1 to be coated is guided over two cylindrical strip guide rolls 4, 5, where the axes 8, 9 of the strip guide rolls are slanted with respect to each other by an angle α. In principle, the diameters of the strip guide rolls could be different. It is advantageous however for the diameters of the two strip guide rolls to be same. To prevent the strip 1 from wandering across the strip guide rolls 4, 5, the direction of strip travel is always perpendicular to the axis of the individual strip guide roll. Because the strip guide rolls 4, 5 are at a slant to each other, the position of the strip 1 is rotated (“twisted”) by the angle α as it travels from one strip guide roll to the other, so that the strip rests with full two-dimensional contact on the strip guide roll in question and can loop around it with practically no slippage.

As the width of the strip 1 to be coated increases and the distance AB between the individual strip sections in the two-dimensional areas becomes larger, the angle α must also be increased. The offset V from one edge of a strip section to the same edge of the adjacent section depends on the slant angle αand on the roll diameter and can be calculated approximately as follows:
V=roll diameter·sin α.

In fact, the individual offsets are not exactly equal because of the geometric situation; they are slightly larger (V+ΔV) at the strip inlet than at the strip outlet. The smaller the slant angle α or the greater the roll diameter, the smaller this offset difference ΔV for the same offset V.

Looping the strip 1 several times back and forth around the strip guide rolls 4, 5 has the effect of creating two “two-dimensional areas”, each of which is formed by the parallel sections of one and the same strip which are being guided parallel to each other. The length L_{2Darea} of these two-dimensional areas corresponds to the distance between the rotational axes of the two strip guide rolls. The effective width B_{2Darea} of the two-dimensional areas is determined by:
the number n of loops of strip passing around the strip guide elements;
the width (Bₛₜᵣᵢₚ) of the strip; and
the distance (AB) between one section of strip and the adjacent section:
   B_{2Darea}=n·Bₛₜᵣᵢₚ+(n−1)·ΔB.

Because of the slant of the strip guide rolls, the two two-dimensional areas are not flat. The wider the two-dimensional areas and the larger the angle α, the greater the deflection of the two-dimensional areas into the 3rd dimension.

If the deflection of the two-dimensional areas is only a few mm to cm, these two-dimensional areas can be coated by standard vacuum coating processes such as sputtering or vapor deposition, where a point on the surface of the strip 1 to be coated passes alternately and repeatedly through the two two-dimensional areas. Both the inside surfaces and the outside surfaces of these two-dimensional areas can be coated. Depending on the coating process being used, the dimensions of the two-dimensional areas are selected so that both the material utilization rate and the required layer properties are optimal. Decreasing the distances AB has the result of reducing the loss of coating material between the strips. On the other hand, a safety gap AB of approximately 0.5-5 mm should be maintained—the exact amount depends on the strip material being used—so that the strip sections do not run over on top of each other, which would cause the strip to be destroyed.

The double-roll arrangement can be positioned in such a way that the strips 1 can be looped around the rolls either vertically or horizontally.

To stabilize the movement of the strip, the surface of the strip guide rolls can be provided with a special profile; for example, the surface can be provided with convexities, as shown in FIG. 4. As a result, the strip 1 will be centered on the highest point of the convexity 10. These surface convexities can be provided on one or both of the strip guide rolls. The radius R of a convexity 10 depends on the predetermined strip tension and on the mechanical properties and thickness of the selected strip material. R should not fall below a certain minimum value in order to ensure that the convexity 1 does not plastically deform the strip 10.

Another advantage of the inventive solution is the possibility of guiding the strip 1 to be coated from the uncoiler and through the process stations to the coiler without the “good” side of the strip 1 coming into contact with the strip guide elements.

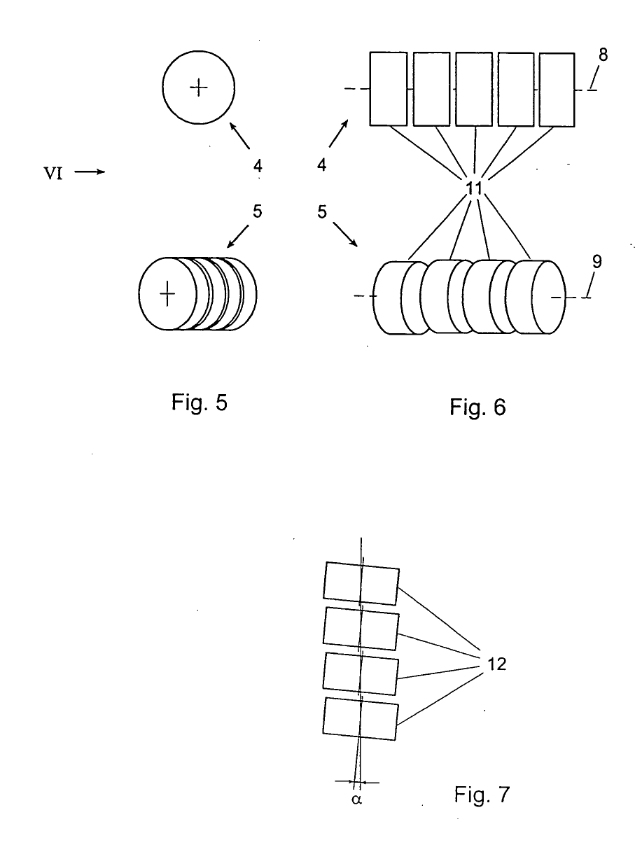

In an advantageous variant II shown in FIGS. 5 and 6, the two cylindrical strip guide rolls 4, 5 are “segmented”, that is, each individual section of the strip is guided over its own separately supported strip guide disk 11. Because the individual strip guide disks 11 are supported separately, they can rotate independently of each other, so that the applied strip tension can be transmitted directly to the individual loops and not transmitted from one to the other by microslippage during operation. In addition, the loops of the strip become free of tension as soon as the tension being applied to the strip is released. The lateral surface of the strip guide disk 11 can again be designed with a convexity to stabilize the position of the strip on the guide disk. It is very difficult, however, to temper the individual strip guide disks.

In another advantageous variant III, as shown in FIG. 7, the slanted, separated strip guide roll 5 of variant II is replaced by a strip guide element composed of several slanted strip guide disks 12, all of which are parallel to each other. The rotational axes of the slanted strip guide disks 12 do not lie on a line but are instead offset from each other, and the center lines of the two strip guide elements are parallel to each other. The two normals to the end surfaces of the strip guide elements 4, 5 are, as shown in FIG. 7, at an angle α to each other. Here, too, the lateral surface of each of the strip guide disks 12 can be designed with a convexity to stabilize the position of the strip on the guide disk 12.

The incoming and outgoing sections of strip and the sections of strip between the strip guide disks 12 run parallel to each other, and the sections of the strip in the area between the strip guide disks are rotated (“twisted”) by the angle α. If we ignore this twisting of the individual strip sections, we see that the strip sections form two two-dimensional areas, the deflection of which into the 3rd dimension is considerably reduced. The maximum deflection lₘₐₓ generated by the twisting of the individual strip sections can be calculated as follows:
lₘₐₓ=½·strip width·sin(α).

Variant III is especially advantageous when coating processes are used in which the coating result depends with great sensitivity on the maintenance of a uniform distance between the coating source and the surface of the strip to be coated. In addition, the strip tension is transmitted without microslippage to all strip sections in the strip guide arrangement. Tempering the individual strip guide disks, however, is very complicated and therefore cannot be recommended.

In an additional advantageous variant IV, at least one of the two guide elements 4, 5 is realized by an arrangement consisting of two parallel guide rolls, the longitudinal axes of which lie in the same parallel plane as that of the single guide element 4 or 5 which they replace, and which thus create an additional two-dimensional area. Here, too, the length L_{2Darea} corresponds to the distance between the axes of the two guide rolls. The diameter of the two rolls can be different. It is advantageous however for the two diameters to be the same.

The pair of rolls forms an effective roll diameter Ø_{eff}, which is calculated from the diameters of the individual rolls Ø₁ and Ø₂ and from the distance L_{2Darea} between the longitudinal axes of the rolls:
Ø_{eff}=L_{2Darea}+½(Ø₁+Ø₂).

The two individual rolls can be made with much smaller diameters than a single strip guide roll can be, because the offset V of the individual strip sections depends on the effective roll diameter Ø_{eff}. Because of the smaller design dimensions, the coating chamber can also be made smaller, which means that an arrangement of this type offers the advantage of lower weight, reduced space requirements, and decreased cost.

When each of the two guide elements 4, 5 according to variant I is replaced by a double-roll arrangement, a “four-roll arrangement” is obtained with a total of four “two-dimensional areas”, all of which can in principle be used for coating. The two double-roll arrangements form two sets of opposing two-dimensional areas. The two-dimensional areas of one of these sets are perfectly flat, whereas the two two-dimensional areas of the other set are slightly deflected into the 3rd dimension (“curved”) as described above.

It is advantageous to design the four-roll arrangement in such a way that all four rolls have the same diameter Øᵣₒₗₗ and that the flat two-dimensional areas are used for coating. The length L_{curved2Darea} of the “curved” two-dimensional areas is made as small as possible to save space. Because the length L_{flat2Darea} is made comparatively long so that sufficient room is available for the coating sources, the effective diameter Ø_{eff} is also comparatively large. Accordingly, as described above, the offset difference ΔV is small, which means that the loss of coating material, i.e., the material which is lost in the AB area between the individual strips, can be kept low.

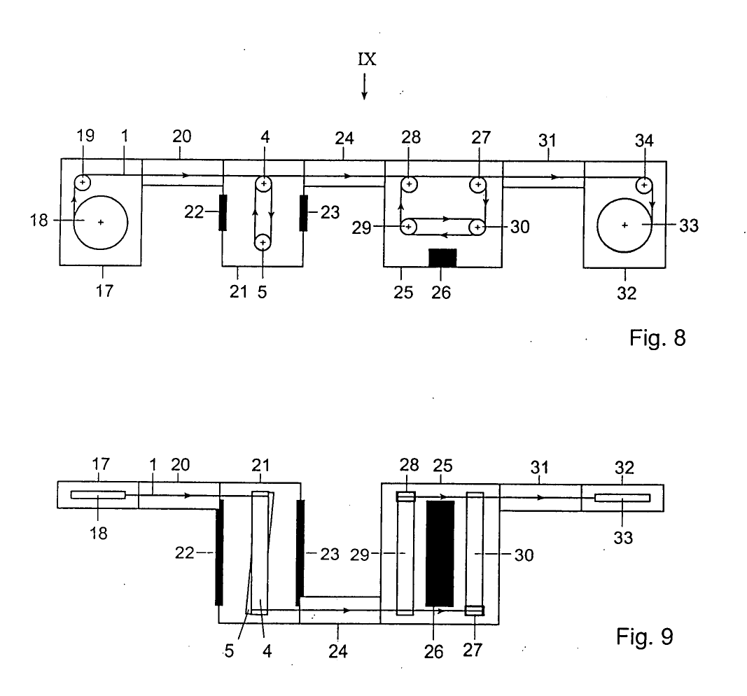

FIG. 8 shows a schematic diagram of a coating system for the strip 1. An uncoiler 18, on which the uncoated strip 1 is coiled, is installed in an uncoiling chamber 17. The strip 1 is guided by a deflecting roll 19 out of the uncoiling chamber 17 to a connecting channel 20 and then passes through the connecting channel 20 into the area of a first process chamber 21. The first process chamber 21 is equipped with sputtering sources 22, 23, which coat the strip 1. The guide elements 4, 5 for the strip 1 are positioned inside the first process chamber 21.

The strip 1 passes from the area of the first process chamber 21 through a connecting channel 24 to the area of a second process chamber 25. The second process chamber 25 has a vapor deposition source 26 for the coating of the strip 1. The strip 1 passes over an inlet-side deflecting roll 27 into the area of the second process chamber 25 and is carried out of the second process chamber 25 over an outlet-side deflecting roll 28. Inside the second process chamber 25, the strip is guided over guide elements 29, 30.

In the first process chamber 21, the guide elements 4, 5 are arranged in such a way that vertically areas of the strip 1 are coated. To increase the coating rate in the first process chamber 21, both the downward-traveling area of the strip 1 on the right and the upward-traveling area on the left are coated by the sputtering sources 22, 23. In the second process chamber 25, the area of the strip 1 to be coated travels essentially horizontally.

From the second process chamber 25, the strip 1 passes through a connecting channel 31 to a coiling chamber 32, in which a coiler 33 is installed. A deflecting roll 34 is provided in an area of the coiling chamber 32 facing the connecting channel 31.

The arrangement according to FIG. 8 is illustrated again in the form of a view from above in FIG. 9. In particular, the skewing of the guide elements 4, 5 designed as strip guide rolls in the first process chamber 21 can be seen. The similar skewing of the strip guide rolls in the second process chamber 25 cannot be seen because of the selected viewing direction.

FIGS. 8 and 9 show in particular a coating system in which the two-dimensional areas are oriented vertically (chamber 21) in one case and horizontally in the other (chamber 25). In principle, any position between these two are also possible. For example, during vapor deposition processes, the vapor is often deposited upwards from below (the vapor deposition source is at the bottom, and the substrate to be coated is located at the top). In the case of sputtering, however, it is often advantageous for the surface to be coated to be oriented vertically. As a result, for example, any particles which may form are prevented from settling on the surface to be coated and causing defects in the final layer. For standard vapor deposition processes, therefore, an arrangement according to chamber 25 is advantageous, whereas, in the case of sputtering, an arrangement according to chamber 21 is advantageous.

By tempering at least one roll of the double-roll arrangement, the strip 1 to be coated can be cooled or heated, depending on the requirements. Because each section of the strip is guided several times over the tempered roll(s), the nominal temperature can be maintained within relatively narrow tolerances. The temperature drift during the coating process is very low.

After the strip 1 has been threaded into a double-roll arrangement, tension is applied to the strip by suitable drive units. As the strip passes through the double-roll arrangement, this strip tension is transmitted very uniformly to all of the strip sections in the double-roll arrangement as a result of microslippage.

According to a preferred embodiment, the outgoing strip 1 is coated with a multilayer system. Each individual layer is deposited as the strip passes through one of the possible coating areas. If all of the coating sources are using the same material for coating, the layer system deposited on the outgoing strip 1 consists exclusively of layers of the same type. If the coating areas in question are coated with different materials, a multilayer system is obtained consisting of a sequence of different individual layers. The layer thicknesses dᵢ of the individual layers i (where i=the number of coating areas multiplied by the number of loops) are determined by the mass flow of the coating source in question to the surface of the strip (static coating rate Rᵢ), whereas they increase in inverse proportion to the velocity vₛₜᵣᵢₚ of the strip:
dᵢ˜Rᵢ·vₛₜᵣᵢₚ⁻¹.
The local static coating rates Rᵢ of a two-dimensional coating source are subject to location-dependent tolerances. Considerable effort is made to minimize these tolerances when, for example, architectural glass is being coated. This is also true for the coating of wide strips or of several narrow strips 1 being guided in parallel. When a strip 1 is transported in accordance with the invention, these tolerances are greatly minimized, because each surface area of the strip 1 passes through the same local coating areas in succession as a result of the multiple looping of the strip 1 around the strip guide rolls.

Although the tolerances for the local static coating rates Rᵢ determine the tolerances for the layer thicknesses of the individual layers, the total layer thickness of all the individual layers together is nearly equal over the entire width of the strip. When the strip width Bₛₜᵣᵢₚ is small in comparison to the width of the two-dimensional areas B_{2Darea}, the tolerances of the local static coating rates Rᵢ have hardly any effect on the thickness layer distribution over the width of the strip. This is true both for multilayer systems consisting of the same layer material and for multilayer systems consisting of different layer materials.

Building multilayer structures makes it possible to obtain certain layer properties which cannot be produced by the deposition of a single layer of the same layer thickness. For example, the transparency of transparent conductive layers (transparent conductive oxides, TCO) can be optimized as a function of the specific electrical conductivity. Standard TCO materials include intrinsic zinc oxide (i-ZnO), aluminum-doped or gallium-doped zinc oxide (ZnO:Al, ZnO:Ga), magnesium-zinc oxide ((Zn, Mg)0), and indium-tin oxide (ITO).

The properties of metallic layers can also be influenced significantly by a multilayer structure. For example, different internal stresses can be produced in the layer by appropriate choice of the coating process parameters. A multilayer structure of molybdenum can be optimized with respect to the internal stresses in the layer in such a way that it improves the growth of the absorber material when used as a rear contact for a solar cell and thus as a substrate for the deposition of a layer of copper-indium diselenide (CuInSe₂, CIS).

Multilayers in which the individual layers consist of different materials can form a “superlattice”. These superlattices can result in very special layer properties. Thus, multilayers with a hardness which is far above that of the individual layers alone can be produced from SiC and SiN. Such multilayers can be used as wear-protection layers.

So-called “multi-quantum wells”, furthermore, can be produced by multilayers with superlattices. Such wells are used as functional coatings on x-ray mirrors and photodetectors and also in the area of laser technology and photonics. Examples of these layer systems include, for example, GaAs, AlGaAs, AlGaAsP, AlGaN, Si/ZnS, Ge/SiGe, Si/Al₂O₃, and also carbon-based systems such as C/WC.

The multilayer structure can be demonstrated by transmission-electron microscopy (TEM).

Both in the vacuum or negative pressure processes and in the processes at standard pressure, some or all of the following advantages can be obtained by applying the inventive process:
high material yield of coating materials at a comparatively low investment level;
high effective dynamic coating rate and thus high strip velocity and short loading times;
very uniform distribution of the layer properties such as thickness, transparency, conductivity, etc., even when inhomogeneous coating sources with large surface areas are used;
low temperature drift because of the use of tempered rolls;
easy-to-scale-up, higher strip velocity by adding more loops;
new layer properties by building multilayer structures;
short coating system length even for slow processes;
low surface-to-volume ratio of the process chamber.

In the case of vacuum processes, it is advantageous to install the deflecting rolls inside the vacuum chamber. In the case of processes under standard pressure, it can be advantageous to position the deflecting roll system outside the chamber, so that the deflecting roll system is not damaged by the process atmosphere. Also, the deflecting roll system itself will not be able to interfere with the process.

An application example of an inventive vacuum coating process is explained in detail in the following. A 42 mm-wide, 100 μm-thick, and 2,000 m-long high-grade steel strip is uncoiled from a vertically clamped coil and guided through a strip guide arrangement with two strip guide rolls 4, 5 (process chamber) in such a way that each of the two-dimensional areas is formed by 10 sections of strip. The diameter of the strip guide rolls is 300 mm; their length is 500 mm; and the distance between their rotational axes is 1 m. The angle α is set at 9°. As a result, the two two-dimensional areas have a height of approximately 450 mm and a length of 1,000 mm.

A commercially available double-magnetron sputtering source is set up on the outward-facing side of each of the two two-dimensional areas, which means that coating is carried out with a total of 4 sputtering sources. Each of these sputtering sources is 50 cm deep and 15 cm high. The outward-facing surfaces of the two areas are coated. The distance from the sputtering sources to the center point of the associated two-dimensional area is approximately 6 cm. Within the two two-dimensional areas, baffle plates are set up to prevent unintentional coating of the rear surface of the strip. The use of additional baffles prevents the strip guide rolls from becoming coated.

The target material is molybdenum. Argon is used as the process gas. The suction power of the vacuum pump is kept constant. The argon gas flow rate is regulated in such a way that that a process pressure of 0.5 Pa is maintained. After a plasma has been ignited, the power of each sputtering source is set at 7.5 kW. The strip to be coated travels through the coating areas at a velocity of vₛₜᵣᵢₚ=4 m/min. After the strip 1 has passed through the coating areas, it has acquired a layer of molybdenum with an average thickness of approximately d_{layer}=0.5 μm on one side of the strip 1. Accordingly, the dynamic coating rate R_{dynamic} of the overall arrangement is:
R_{dynamic}=d_{layer}·vₛₜᵣᵢₚ=0.5 μm ·4 m/min=2 μm·m/min.

The coated strip 1 is conducted to a coiler, which winds the strip up into a coil again. The 2,000 m-long strip has acquired its finished coating after a time of approximately 8 hours and 20 minutes. The useful life of 10 mm-thick Mo targets is more than 100 hours. During this period of time, approximately 25 km of strip 1 can be coated, which is equivalent to 1,050 m².

Cu, In, and Ga are then electrodeposited on this Mo-coated high-grade steel strip. Se and NaF are then vapor-deposited under vacuum on top of that. During this vapor deposition process, the strip is guided in accordance with the invention. This so-called “precursor” is converted to the crystalline chalcopyrite phase by tempering it at 500° C. Then a thin indium sulfide layer is deposited on top according to the invention (see below). The final step is another sputtering process, in which again the inventive strip guidance system is used to apply a conductive window layer of intrinsic zinc oxide and aluminum-doped zinc oxide. A two-dimensional area of 1 cm² is then separated on the strip 1 by scratching. This solar cell demonstrates an efficiency of 11% in a sun simulator.

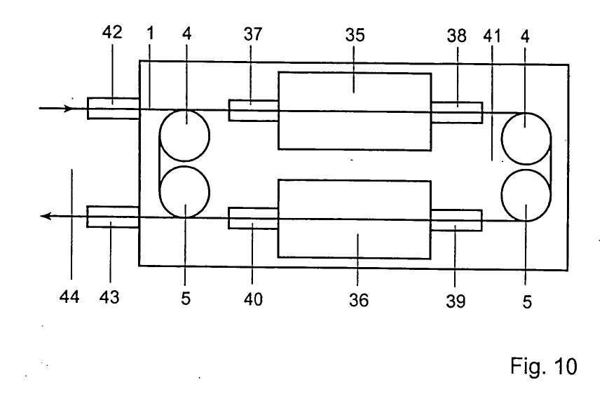

Another application example according to FIG. 10 pertains to an inventive normal-pressure process for the deposition of an indium sulfide buffer layer on a 0.1 mm-thick, 42 mm-wide, and 2,000 m-long continuously traveling high-grade steel strip 1. It represents a continuous strip coating process. The strip 1 is guided over a 4-roll arrangement 4, 5 in such a way that it travels several times in succession through two process chambers 35, 36. The gas space of each of the two process chambers 35, 36 is separated by an entrance lock 37, 39 and an exit lock 38, 40 from the surrounding inert gas space 41, in which the 4-roll arrangement 4, 5 is located. The strip 1 is fed from the outside air 44 into the chamber of the inert gas space 41 through one air lock 42 and taken back out again through another air lock 43; the uncoiler and the coiler for the strip are located outside the chamber of the inert gas space 41 and are not shown in FIG. 10.

During processing, the strip 1, which has already been coated with the CIS absorber, travels from the uncoiler through the air entrance lock 42 and the entrance lock 37 into the first process chamber 35. There the strip 1 is heated to 200° C. At the same time, an indium salt solution is sprayed onto the side coated with the CIS absorber. Ethanol or water can be used as the solvent. By evaporating the solvent, a few nanometers-thick indium salt layer is formed on the side of the strip 1 coated with the CIS absorber. The feed of the indium salt solution and the evacuation of the off-gases are not shown in FIG. 10.

The strip 1 leaves the process chamber 35 through the exit lock 38 and is guided by way of the 4-roll arrangement 4, 5 and the entrance lock 39 into the process chamber 36. Here the indium salt layer reacts with the hydrogen sulfide gas introduced into the process chamber 36 to form an indium sulfide layer (sulfurization) only a few nanometers thick. For this reaction, the strip 1 is heated to 200° C. in the process chamber. The feed of the hydrogen sulfide gas and the evacuation of the off-gases are not shown in FIG. 10.

The strip 1 coated on one side with CIS/indium sulfide leaves the process chamber 36 via the exit lock 40 and is guided via the 4-roll arrangement 4, 5 and the entrance lock 37 back into the process chamber 35, where it is again coated with a thin layer of indium salt. In correspondence with the number of times the strip is looped around the 4-roll arrangement 4, 5, the cycle of indium salt deposition and subsequent sulfurization is repeated as often as necessary to obtain the desired layer thickness of, for example, 30 nm. Then the strip 1 coated on one side with CIS and a multilayer structure of indium sulfide leaves the inert gas space 41 via the air exit lock 43 and is coiled up by the coiler.

The deposited indium sulfide layer is used as a buffer layer during the production of CuInSe₂-based (“CIS”) thin-layer solar cells.

While specific embodiments of the invention have been shown and described in detail to illustrate the inventive principles, it will be understood that the invention may be embodied otherwise without departing from such principles.

We claim:

1. A process for coating a strip in which the strip is transported along a strip guide inside a coating chamber, the process comprising
slanting the longitudinal axes (8, 9) of at least two guide elements (4, 5) of the strip guide (2), which are positioned a certain distance apart, relative to each other such that the longitudinal axes (8, 9) lie on planes which are a certain distance apart and essentially parallel to each other, wherein the distance (3) between the guide elements (3, 4) varies along the longitudinal axes (8, 9); and
conducting the strip (1) over the guide elements (4, 5) inside the coating chamber such that at least two sections of strip (1) are essentially adjacent to each other as they are being coated.

2. A process according to claim 1, comprising conducting the strip (1) over rotationally symmetric guide elements (4, 5) in the form of rolls, and especially in the form of cylinders.

3. A process according to claim 1, comprising coating a strip (1) consisting essentially of metal.

4. A process according to claim 1, comprising coating a strip (1) consisting essentially of plastic.

5. A process according to claim 1, comprising coating a strip (1) consisting essentially of textile material.

6. A process according to claim 1, comprising conducting the strip (1) resting with full two-dimensional contact over the guide elements (4, 5).

7. A process according to claim 1, comprising tempering at least one of the guide elements (4, 5).

8. A process according to claim 7, comprising heating at least one of the guide elements (4, 5).

9. A process according to claim 7, comprising cooling at least one of the guide elements (4, 5).

10. A process according to claim 1, comprising tensioning the strip (1).

11. A process according to claim 1, comprising performing a multilayer coating operation.

12. A process according to claim 11, comprising coating the strip (1) several times with the same material.

13. A process according to claim 11, comprising coating the strip (1) with at least two different materials.

14. A process according to claim 1, comprising coating a strip intended to serve as a basis material for solar cells.

15. A process according to claim 1, wherein the longitudinal axes (8, 9) are slanted relative to each other by a slant angle (α) havingue in the range of 0.1-45°, and preferably in the range of 1-10°.

16. A process according to claim 1, wherein at least one of the two guide elements (4, 5) is comprised of at least two rolls extending parallel to each other.

17. A process according to claim 1, wherein each of the two guide elements (4, 5) is comprised of two parallel rolls; and wherein the sections of the strip which are traveling essentially next to each other form two flat and two curved two-dimensional areas, at least one of which is used for coating.

18. A process according to claim 1, comprising conducting the strip (1) by at least one guide element (4, 5) divided into at least two segments.

19. A process according to claim 1, comprising carrying out coating at an effective negative pressure.

20. A process according to claim 1, comprising carrying out coating at essentially standard pressure.

21. A device for coating a strip, the device comprising strip guide installed in a coating chamber, wherein the strip guide has at least two guide elements (4, 5) arranged a certain distance (3) apart, the longitudinal axes (8, 9) of the guides being slanted relative to each other, wherein the longitudinal axes (8, 9) lie on planes which are a certain distance apart and essentially parallel to each other, wherein a distance between the guide elements (4, 5) changes along the longitudinal axis; and wherein at least two sections of the strip are guided essentially adjacent to each other as they are being coated.

22. A device according to claim 21, wherein at least one of the guide elements (4, 5) is a roll.

23. A device according to claim 21, wherein the strip (1) is metal.

24. A device according to claim 21, wherein the strip (1) is plastic.

25. A device according to claim 21, wherein the strip (1) is textile material.

26. A device according to claim 21, wherein the guide elements (4, 5) are oriented such that the strip (1) rests with full two-dimensional contact on the guide elements.

27. A device according to claim 21, wherein at least one of the guide elements (4, 5) comprises a tempering means.

28. A device according to claim 21, wherein at least one of the guide elements (4, 5) comprises a heating means.

29. A device according to claim 21, wherein at least one of the guide elements (4, 5) comprises a cooling means.

30. A device according to claim 21, wherein the strip guide (2) comprising at least one strip tensioner.

31. A device according to claim 21, wherein the strip guide (2) is configured to support the formation of a multilayer coating on the strip (1).

32. A device according to claim 21, wherein the strip guide (2) is configured to support the formation of a multilayer coating on the strip (1) consisting of the same material.

33. A device according to claim 21, wherein the strip guide (2) is configured to support the formation of a multilayer coating on the strip (1) consisting of at least two different materials.

34. A device according to claim 21, wherein the device is configured to produce a strip (1) which is suitable for use as a basis material for solar cells.

35. A device according to claim 21, wherein the longitudinal axes (8, 9) of the guide elements (4, 5) are slanted with respect to each other at a slant angle (a) in the range of 2-10°.

36. A device according to claim 21, wherein at least one of the two guide elements (4, 5) is comprised of at least two rolls which are parallel to each other.

37. A device according to claim 21, wherein each of the two guide elements (4, 5) is comprised of two parallel rolls, wherein sections of the strip traveling essentially adjacent to each other form two flat and two curved two-dimensional areas, at least one of which is used for the coating operation.

38. A device according to claim 21, wherein at least one of the guide elements (4, 5) is divided into at least two segments in the direction of the longitudinal axis (8, 9).

39. A device according to claim 21, wherein the device is configured to conduct the coating operation at an effective negative pressure.

40. A device according to claim 21, wherein the device is configured to conduct the coating operation at essentially standard pressure.
